(19) United States
(12) Patent Application Publication
(10) Pub. No.: US 2004/0251946 A1
(43) Pub. Date: Dec. 16, 2004

(54) Analog delay circuit

(76) Inventor: Hiroshi Miyagi, Niigata (JP)

Correspondence Address: DELLETT AND WALTERS, P. O. BOX 2786, PORTLAND, OR, 97208-2786, US

(21) Appl. No.: 10/494,656

(22) PCT Filed: Nov. 12, 2002
(86) PCT No.: PCT/JP02/11760

(30) Foreign Application Priority Data
Nov. 13, 2001 (JP) 2001-347281

(51) Int. Cl. H03H 11/26

(52) U.S. Cl. 327/277

(57) ABSTRACT

An analog delay circuit integrally formable on a semiconductor substrate and providing an improvement in accuracy of delay time. An analog delay circuit 24 includes a clock generating section 50, analog switches 51-56, 61-66, inverter circuits 71-76, and capacitors 81-86, 90. The switches 51-56 are sequentially rendered conductive, thereby causing capacitors 81-86 to hold the voltages of input signals at the respective time points. Before these held voltages are updated, the switches 61-66 are rendered conductive, thereby deriving the held voltages. In this way, the time periods from when the switches 51-56 are rendered conductive to when the respectively associated switches 61-66 are rendered conductive, that is, signal output timings are delayed.

### TECHNICAL FIELD

The present invention relates to an analog delay circuit for delaying an output timing of an inputted analog signal.

### BACKGROUND ART

A signal inputted and outputted in an AM receiver or an FM receiver for in-vehicle use is apt to be mixed with noise generated by other in-vehicle equipment. For this reason, various denoising circuits have been adopted so far. For instance, there is a technique among them, wherein a noise component is extracted from the signal, a part of the signal corresponding to the noise component is masked and a voltage of the signal inputted immediately before is held so as to eliminate the noise. According to this technique, a pulse signal is generated for the sake of masking the noise. To mask the noise with this pulse signal, however, it is necessary to match a generation timing of the noise with the generation timing of the pulse signal generated based on this noise. As a matter of course, a predetermined time is necessary to generate the pulse signal, and so it requires an analog delay circuit for delaying the signal of which noise is to be eliminated for the predetermined time. A Bessel type filter of a plurality of stages (four stages for instance) has been used as this analog delay circuit.

The above-mentioned Bessel type filter is constituted by combining a resistance, a capacitor and an operational amplifier. Therefore, there has been a problem that, considering element constants of the resistances and capacitors, the entire analog delay circuit cannot be integrally formed on a semiconductor substrate. Even if the resistances and capacitors of large element constants are formed on the semiconductor substrate, there has been a problem that, variations in the element constants of the resistances and so on formed on the semiconductor substrate are such that delay time of the analog delay circuit significantly varies. In particular, to correctly eliminate only the noise, it is necessary to precisely set the delay time of the analog delay circuit, and it is difficult to satisfy this precision demand with the analog delay circuit using the Bessel type filter formed on the semiconductor substrate.

### DISCLOSURE OF THE INVENTION

The present invention has been created in consideration of these points, and an object thereof is to provide an analog delay circuit capable of being integrally formed on a semiconductor substrate and improving precision of delay time.

To solve the above-mentioned problems, the analog delay circuit according to the present invention comprises a plurality of capacitors, a plurality of first switches for supplying an input signal to each of the plurality of capacitors in a different timing and in predetermined order to have a voltage of the input signal corresponding to a supply timing held by each of the plurality of capacitors, and a plurality of second switches for taking out the voltage of the input signal held by each of the plurality of capacitors before the next timing for holding the voltage comes. Thus, it is possible to render the first switches conductive sequentially to have the voltage of the input signal at each point in time held by each capacitor and render the second switches conductive to take out a hold voltage before updating it so as to delay an output timing of the signal just for a time period from rendering the first switches conductive until rendering the second switches conductive. In particular, as it is constituted by using the first and second switches capable of switching an intermittent state and the capacitors for holding the voltage of the signal, it is possible to easily form the entire circuit on the semiconductor substrate without necessity of using resistances and capacitors of large element constants. And it is possible to improve the precision of the delay time irrespective of variations in the element constants because the time period from rendering the first switches conductive until rendering the second switches conductive becomes the delay time of the signal.

It is desirable to connect output terminals of the above-mentioned second switches in common. It is thereby possible to output the voltage of the signals held dispersedly by each of the plurality of capacitors as successive signals.

It is also desirable to further comprise capacitors for smoothing connected to the output terminals of the above-mentioned second switches and selectively connected in parallel to each of the plurality of capacitors. It is thereby possible to successively take out the voltage held by each of the plurality of capacitors.

It is also desirable that an electrostatic capacity of the above-mentioned capacitor for smoothing is smaller than that of each of the plurality of capacitors. It is thereby possible to decrease reduction in the voltage on taking out the voltage held by each of the plurality of capacitors.

It is also desirable to render the above-mentioned first switches exclusively conductive. Or it is desirable to render the above-mentioned second switches exclusively conductive. It is thereby possible to perform charging and discharging operations of each of the plurality of capacitors separately so as to stabilize the charging and discharging operations of each of the capacitors.

It is also desirable that each of the above-mentioned first and second switches is an analog switch having a p-channel type FET and an n-channel type FET connected in parallel. It is thereby possible to render resistance values of the first and second switches on conduction almost constant irrespective of the voltage of the input signal so as to prevent occurrence of distortion of an output signal due to a change in the voltage of the input signal.

### BRIEF DESCRIPTION OF THE DRAWINGS

FIG. 1 is a diagram showing a partial configuration of an FM receiver including an analog delay circuit according to an embodiment;

FIG. 2 is a diagram showing a configuration of a denoising circuit shown in FIG. 1;

FIG. 3 is a diagram showing a detailed configuration of the analog delay circuit; and

FIG. 4 is a diagram showing an operation timing of the analog delay circuit.

### BEST MODE FOR CARRYING OUT THE INVENTION

Hereafter, a description will be given by referring to the drawings as to an analog delay circuit according to an embodiment to which the present invention is applied.

FIG. 1 is a diagram showing a partial configuration of an FM receiver including an analog delay circuit according to an embodiment. As shown in FIG. 1, the FM receiver according to this embodiment is comprised of an FM detector circuit 10, a denoising circuit 20 and a stereo demodulation circuit 30. The FM detector circuit 10 performs an FM detection process to an intermediate frequency signal amplified by an intermediate-frequency amplifier circuit (not shown) so as to output a stereo composite signal. The denoising circuit 20 eliminates noise included in an FM stereo composite signal inputted from the FM detector circuit 10. The stereo demodulation circuit 30 performs a stereo demodulation process for separating an L signal and an R signal included in an inputted stereo composite signal.

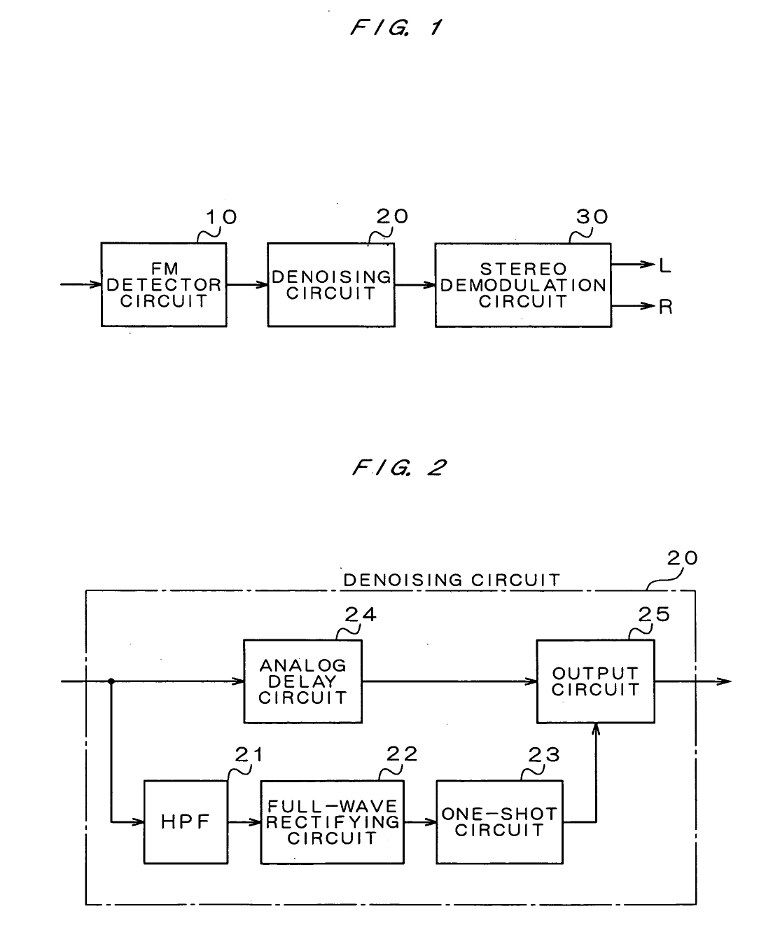

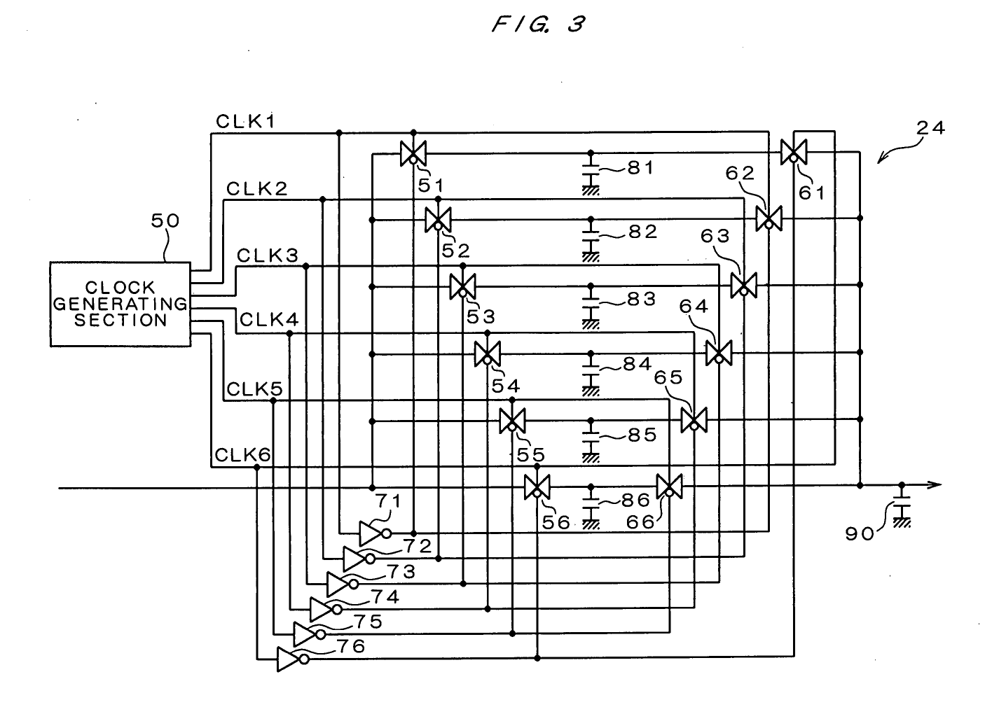

FIG. 2 is a diagram showing a configuration of the denoising circuit 20 shown in FIG. 1. As shown in FIG. 2, the denoising circuit 20 is comprised of a high-pass filter (HPF) 21, a full-wave rectifying circuit 22, a one-shot circuit 23, an analog delay circuit 24 and an output circuit 25. The high-pass filter 21 passes only a high-frequency component including the noise component included in the stereo composite signal outputted from the FM detector circuit 10. The full-wave rectifying circuit 22 performs full-wave rectification to the noise component outputted from the high-pass filter 21. In general, the noise of a negative polarity as well as a positive polarity may be mixed with a signal having a predetermined voltage level, and so the full-wave rectifying circuit 22 rectifies two kinds of noise of different polarities so as to generate the noise component of the same polarity. The one-shot circuit 23 compares the noise component rectified by the full-wave rectifying circuit 22 to a predetermined reference voltage Vref, and generates a pulse corresponding to the noise of which crest value exceeds the reference voltage Vref.

The analog delay circuit 24 outputs the inputted stereo composite signal by delaying it for a predetermined time. This delay time is set correspondingly to processing time of the circuits of the above-mentioned high-pass filter 21 to the one-shot circuit 23. The output circuit 25 interrupts the stereo composite signal outputted from the analog delay circuit 24 when the pulse outputted from the one-shot circuit 23 is inputted, and passes the stereo composite signal at other times.

FIG. 3 is a diagram showing a detailed configuration of the analog delay circuit 24. As shown in FIG. 3, the analog delay circuit 24 is comprised of a clock generating section 50, analog switches 51 to 56, 61 to 66, inverter circuits 71 to 76 and capacitors 81 to 86 and 90. The above-mentioned analog switches 51 to 56 are corresponding to first switches, and the analog switches 61 to 66 are corresponding to second switches.

The clock generating section 50 generates six clock signals CLKs 1 to 6 of which output timing is mutually different in predetermined order. The six clock signals CLKs 1 to 6 have the same period, and are set to have a high-level period which is mutually exclusive and cyclic.

The first clock signal CLK 1 is inputted to the two analog switches 51 and 62 directly or via the inverter circuit 71. If the one analog switch 51 conducts correspondingly to the clock signal CLK 1, the voltage of the input signal in this conduction timing is applied to the capacitor 81, and the applied voltage is held by the capacitor 81. If the other analog switch 62 conducts correspondingly to the clock signal CLK 1, one end of the capacitor 82 is connected to an output terminal side, and a hold voltage of the capacitor 82 is taken to the outside as an output voltage.

The second clock signal CLK 2 is inputted to the two analog switches 52 and 63 directly or via the inverter circuit 72. If the one analog switch 52 conducts correspondingly to the clock signal CLK 2, the voltage of the input signal in this conduction timing is applied to the capacitor 82, and the applied voltage is held by the capacitor 82. If the other analog switch 63 conducts correspondingly to the clock signal CLK 2, one end of the capacitor 83 is connected to the output terminal side, and the hold voltage of the capacitor 83 is taken to the outside as the output voltage.

The third clock signal CLK 3 is inputted to the two analog switches 53 and 64 directly or via the inverter circuit 73. If the one analog switch 53 conducts correspondingly to the clock signal CLK 3, the voltage of the input signal in this conduction timing is applied to the capacitor 83, and the applied voltage is held by the capacitor 83. If the other analog switch 64 conducts correspondingly to the clock signal CLK 3, one end of the capacitor 84 is connected to the output terminal side, and the hold voltage of the capacitor 84 is taken to the outside as the output voltage.

The fourth clock signal CLK 4 is inputted to the two analog switches 54 and 65 directly or via the inverter circuit 74. If the one analog switch 54 conducts correspondingly to the clock signal CLK 4, the voltage of the input signal in this conduction timing is applied to the capacitor 84, and the applied voltage is held by the capacitor 84. If the other analog switch 65 conducts correspondingly to the clock signal CLK 4, one end of the capacitor 85 is connected to the output terminal side, and the hold voltage of the capacitor 85 is taken to the outside as the output voltage.

The fifth clock signal CLK 5 is inputted to the two analog switches 55 and 66 directly or via the inverter circuit 75. If the one analog switch 55 conducts correspondingly to the clock signal CLK 5, the voltage of the input signal in this conduction timing is applied to the capacitor 85, and the applied voltage is held by the capacitor 85. If the other analog switch 66 conducts correspondingly to the clock signal CLK 5, one end of the capacitor 86 is connected to the output terminal side, and the hold voltage of the capacitor 86 is taken to the outside as the output voltage.

The sixth clock signal CLK 6 is inputted to the two analog switches 56 and 61 directly or via the inverter circuit 76. If the one analog switch 56 conducts correspondingly to the clock signal CLK 6, the voltage of the input signal in this conduction timing is applied to the capacitor 86, and the applied voltage is held by the capacitor 86. If the other analog switch 61 conducts correspondingly to the clock signal CLK 6, one end of the capacitor 81 is connected to the output terminal side, and the hold voltage of the capacitor 81 is taken to the outside as the output voltage.

The capacitor 90 is for smoothing, and is connected to output terminals of the analog switches 61 to 66. And when all of them are in a nonconductive state, it maintains the hold voltages of the capacitors 81 to 86 taken out on the output terminal side immediately before that. For instance, an electrostatic capacity of the capacitor 90 is set at a value sufficiently small against the electrostatic capacities of the respective capacitors 81 to 86. And when one of the capacitors 81 to 86 is connected in parallel to the capacitor 90, the voltage at both ends of the capacitor 90 becomes almost equal to the voltages at both ends of the connected capacitors 81 to 86. Each of the above-mentioned analog switches 51 to 56, 61 to 66 is constituted by connecting a p-channel type FET and an n-channel type FET in parallel. For this reason, on resistance is almost constant even if the voltage level of the input signal changes so as to prevent occurrence of distortion of the output signal due to the change in the voltage level of the input signal.

The analog delay circuit 24 according to this embodiment has such a configuration, and operation thereof will be described below.

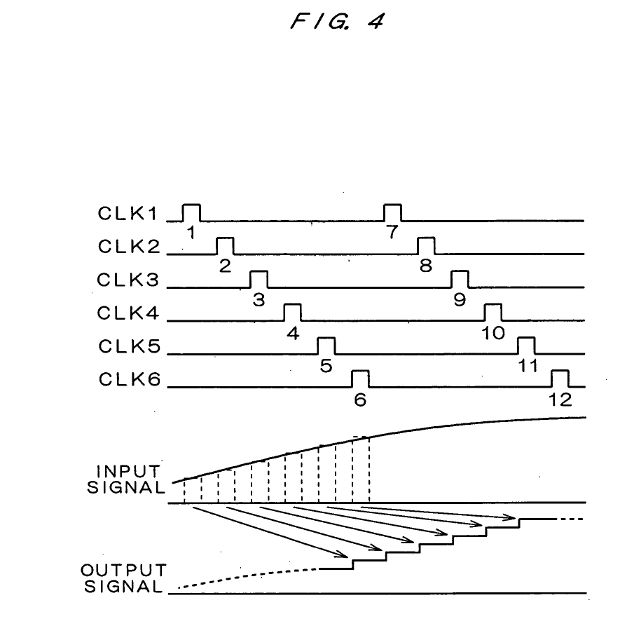

FIG. 4 is a diagram showing an operation timing of the analog delay circuit 24. In FIG. 4, numbers 1 to 12 given to the clock signals CLKs 1 to 6 denote output order (order in which the clock signals exclusively become high-level) of the clock signals.

If the clock signal CLK 1 is inputted first (number 1), the analog switch 51 is rendered conductive in this timing and the capacitor 81 is charged so that the voltage of the input signal is held. Likewise, if the clock signal CLK 2 is inputted next (number 2), the analog switch 52 is rendered conductive in this timing and the capacitor 82 is charged so that the voltage of the input signal is held.

Thus, if the clock signal CLKs 1 to 6 are sequentially inputted, the corresponding analog switches 51 to 56 are rendered conductive so that the voltages of the input signals are held by the capacitors 81 to 86 connected to the following stages.

The voltages held by the capacitors 81 to 86 respectively are taken out in a timing immediately before they are updated next. To be more precise, the clock signal CLK 1 (number 7) is outputted again after the clock signal CLK 6 (number 6) is outputted, and so the analog switch 61 connected to the capacitor 81 is rendered conductive in timing for outputting the clock signal CLK 6 so that the hold voltage of the capacitor 81 is taken out to the output terminal side. Thereafter, the analog switches 62 to 66 are sequentially rendered conductive so that the hold voltages of the capacitor 82 to 86 are sequentially taken out.

Thus, the switches 51 to 56 are rendered conductive sequentially to have the voltage of the input signal at each point in time held by each of the capacitors 81 to 86, and the switches 61 to 66 are rendered conductive to take out the hold voltage before updating it. It is thereby possible to delay the output timing of the signal just for a time period from rendering the switches 51 to 56 conductive until rendering the corresponding switches 61 to 66 conductive.

In particular, as the analog delay circuit 24 can be constituted by using the switches 51 to 56, 61 to 66 capable of switching an intermittent state, the capacitors 81 to 86 for holding the voltage of the signal and other additional circuits such as the clock generating section 50, it is possible to easily form the entire analog delay circuit 24 on the semiconductor substrate without necessity of using the resistances and capacitors of large element constants.

As the time period from rendering the switches 51 to 56 conductive until rendering the corresponding switches 61 to 66 conductive becomes the delay time of the signal, it is possible to accurately set the delay time by the generation timing of the clock signals and the numbers of the analog switches and capacitors so as to improve the precision of the delay time.

It is also possible, by connecting the output terminals of the analog switches 61 to 66 in common, to output the voltage of the signals held dispersedly by each of the plurality of capacitors 81 to 86 as successive signals. It is also possible, by connecting the capacitor 90 for smoothing to the output terminals of the analog switches 61 to 66, to successively take out the voltage held by each of the plurality of capacitors 81 to 86. In particular, it becomes possible, by rendering the electrostatic capacity of the capacitor 90 for smoothing sufficiently smaller than that of each of the plurality of capacitors 81 to 86, to decrease reduction in the voltage on taking out the voltage held by each of the plurality of capacitors 81 to 86.

It is also possible, by rendering the plurality of analog switches 51 to 56 exclusively conductive and rendering the plurality of analog switches 61 to 66 exclusively conductive, to perform charging and discharging operations of each of the plurality of capacitors 81 to 86 separately so as to stabilize the charging and discharging operations of each of the capacitors 81 to 86.

The present invention is not limited to the above embodiment but allows various modified embodiments in the scope of the invention. For instance, the above-mentioned embodiment described the analog delay circuit 24 included in the denoising circuit 20 of the FM receiver. It is also possible, however, to apply the present invention to the analog delay circuit used for various receivers such as an AM receiver or uses other than the receivers.

Industrial Applicability

As described above, according to the present invention, it is possible to render the first switches conductive sequentially to have the voltage at each point in time held by each capacitor and render the second switches conductive to take out the voltage before updating it so as to delay the output timing of the signal just for a time period from rendering the first switches conductive until rendering the second switches conductive. In particular, as it is constituted by using the first and second switches capable of switching an intermittent state and the capacitors for holding the voltage of the signal, it is possible to easily form the entire circuit on the semiconductor substrate without necessity of using resistances and capacitors of large element constants. And it is possible to improve the precision of the delay time irrespective of variations in the element constants because the time period from rendering the first switches conductive until rendering the second switches conductive becomes the delay time of the signal.

1. An analog delay circuit comprising:
a plurality of capacitors;
a plurality of first switches for supplying an input signal to each of the plurality of capacitors in a different timing and in predetermined order to have a voltage of said input signal corresponding to a supply timing held by each of said plurality of capacitors; and
a plurality of second switches for taking out the voltage of said input signal held by each of said plurality of capacitors before the next timing for holding the voltage comes.

2. The analog delay circuit according to claim 1, characterized by connecting output terminals of said plurality of second switches in common.

3. The analog delay circuit according to claim 2, characterized by further comprising capacitors for smoothing connected to the output terminals of said plurality of second switches and selectively connected in parallel to each of said plurality of capacitors.

4. The analog delay circuit according to claim 3, characterized in that an electrostatic capacity of said capacitor for smoothing is smaller than that of each of said plurality of capacitors.

5. The analog delay circuit according to claim 1, characterized by rendering each of said plurality of first switches exclusively conductive.

6. The analog delay circuit according to claim 1, characterized by rendering each of said plurality of second switches exclusively conductive.

7. The analog delay circuit according to claim 1, characterized in that each of said first and second switches is an analog switch having a p-channel type FET and an n-channel type FET connected in parallel.
